(19) United States
(12) Patent Application Publication
(10) Pub. No.: US 2020/0067271 A1
(43) Pub. Date: Feb. 27, 2020

(54) Projector

(71) Applicants: Seiko Epson Corporation, Tokyo (JP); Sophia School Corporation, Tokyo (JP)

(72) Inventors: Koichiro AKASAKA, Ina-shi (JP); Hiroki NISHIOKA, Tokyo (JP); Shunsuke ISHIZAWA, Tokyo (JP); Takafumi NODA, Matsumoto-shi (JP); Yasutaka IMAI, Suwa-shi (JP); Katsumi KISHINO, Tokyo (JP); Hiroyasu KASEYA, Fujimi-machi (JP); Tsuyoshi KANEKO, Shimosuwa-machi (JP)

(21) Appl. No.: 16/546,665

(22) Filed: Aug. 21, 2019

(30) Foreign Application Priority Data
Aug. 22, 2018 (JP) 2018-155398

(51) Int. Cl. H01S 5/10; G03B 21/20; H01S 5/343

(52) U.S. Cl. CPC H01S 5/105; G03B 21/2033; G03B 33/12; H01S 5/34333; G03B 21/2013

(57) ABSTRACT

A projector includes a laser light source, and a light modulating element that modulates light emitted from the laser light source in accordance with image information. The laser light source includes a substrate, and a photonic crystal structure that includes a light emitting layer that emits light, and causes the light emitted by the light emitting layer to be confined in an in-plane direction of the substrate and be emitted in a normal direction of the substrate.

Japanese Patent Application No. 2018-155398 filed on Aug. 22, 2018 is hereby incorporated by reference in its entirety.

### BACKGROUND OF THE INVENTION

The present disclosure relates to a projector.

In recent years, there has been an increasing demand for projectors to perform projection on large screens in a brighter environment, particularly in a digital signage market and an educational market, and higher brightness has been required. Further, mercury lamps that have been widely used as light sources for projectors have a lifespan problem of becoming increasingly dark and abruptly going off, and an environmental problem of mercury regulations. Thus, a light source of a projector gradually transitions to a solid light source such as a light emitting diode (LED) and a laser that emit light at high brightness and are environmentally friendly with a long lifetime.

For example, JP-A-2007-94384 describes a projector including an LED light source, a liquid crystal display panel, a cross dichroic prism, and a projection lens.

However, in JP-A-2007-94384, the LED light source is provided with a rod integrator between the LED light source and the liquid crystal display panel in order to uniformly illuminate the liquid crystal display panel. Therefore, a size increases, and it is difficult to reduce the size.

### SUMMARY

A projector according to a first aspect of the present disclosure including:

a laser light source; and

a light modulating element that modulates light emitted from the laser light source in accordance with image information,

the laser light source including:

a substrate; and

a photonic crystal structure that includes a light emitting layer that emits light, and causes the light emitted by the light emitting layer to be confined in an in-plane direction of the substrate and be emitted in a normal direction of the substrate.

A projector according to a second aspect of the present disclosure including:

a laser light source; and

a light modulating element that modulates light emitted from the laser light source in accordance with image information,

the laser light source including:

a substrate;

a light emitting layer that emits light; and

a photonic crystal structure that causes the light emitted by the light emitting layer to be confined in an in-plane direction of the substrate and be emitted in a normal direction of the substrate.

### BRIEF DESCRIPTION OF THE SEVERAL VIEWS OF THE DRAWING

FIG. 1 is a diagram schematically illustrating a projector according to a first embodiment.

FIG. 2 is a cross-sectional view schematically illustrating a laser light source of the projector according to the first embodiment.

FIG. 3 is a plan view schematically illustrating a light emitting element of the projector according to the first embodiment.

FIG. 4 is a plan view schematically illustrating a photonic crystal structure of the projector according to the first embodiment.

FIG. 5 is a cross-sectional view schematically illustrating a manufacturing step of the laser light source of the projector according to the first embodiment.

FIG. 6 is a cross-sectional view schematically illustrating a manufacturing step of the laser light source of the projector according to the first embodiment.

FIG. 7 is a cross-sectional view schematically illustrating a manufacturing step of the laser light source of the projector according to the first embodiment.

FIG. 8 is a plan view schematically illustrating a light modulating element of the projector according to the first embodiment.

FIG. 9 is a cross-sectional view schematically illustrating the light modulating element of the projector according to the first embodiment.

FIG. 10 is a graph illustrating a relationship between a maximum incident angle of light incident on a transmissive type liquid crystal light valve and a transmittance of light in a projection lens.

FIG. 11 is a cross-sectional view schematically illustrating the light emitting element of the projector according to the first embodiment.

FIG. 12 is a cross-sectional view schematically illustrating a laser light source of a projector according to a first modified example of the first embodiment.

FIG. 13 is a cross-sectional view schematically illustrating a light emitting element of a projector according to a second modified example of the first embodiment.

FIG. 14 is a cross-sectional view schematically illustrating a light emitting element of a projector according to a second embodiment.

FIG. 15 is a plan view schematically illustrating a photonic crystal structure of the projector according to the second embodiment.

FIG. 16 is a cross-sectional view schematically illustrating a light emitting element of a projector according to a modified example of the second embodiment.

### DETAILED DESCRIPTION OF THE EMBODIMENT

A projector according to one embodiment of the present disclosure including:

a laser light source; and

a light modulating element that modulates light emitted from the laser light source in accordance with image information,

the laser light source including:

a substrate; and

a photonic crystal structure that includes a light emitting layer that emits light, and causes the light emitted by the light emitting layer to be confined in an in-plane direction of the substrate and be emitted in a normal direction of the substrate.

In the projector,

the photonic crystal structure may include columnar portions arranged periodically.

In the projector,

Each of the columnar portions may include the light emitting layer.

In the projector,

the photonic crystal structure may include a layer provided with pores periodically.

In the projector,

the layer may include the light emitting layer.

A projector according to one aspect of the present disclosure including:

a laser light source; and

a light modulating element that modulates light emitted from the laser light source in accordance with image information,

the laser light source including:

a substrate;

a light emitting layer that emits light; and

a photonic crystal structure that causes the light emitted by the light emitting layer to be confined in an in-plane direction of the substrate and be emitted in a normal direction of the substrate.

In the projector,

the photonic crystal structure may include columnar portions arranged periodically.

In the projector,

the photonic crystal structure may include a layer provided with pores periodically.

Preferred embodiments of the present disclosure are described in detail below with reference to the drawings. Note that the following embodiments do not unduly limit the scope of the present disclosure as stated in the claims. In addition, all of the elements described below are not necessarily essential requirements of the present disclosure.

### 1. First Embodiment

### 1.1. Projector

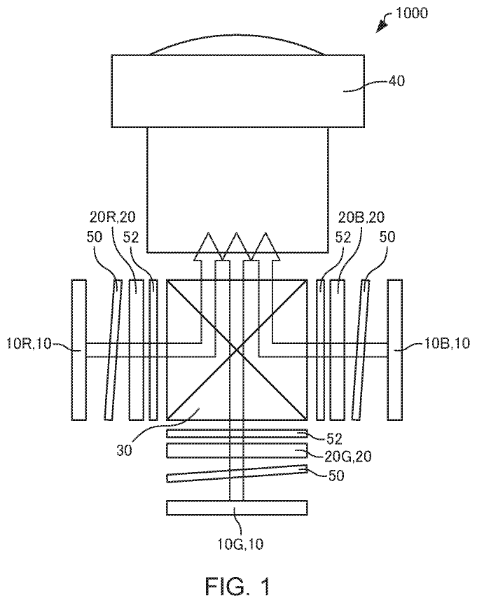

First, a projector according to a first embodiment will be described with reference to the drawings. FIG. 1 is a diagram schematically illustrating a projector 1000 according to the first embodiment.

As illustrated in FIG. 1, the projector 1000 includes, for example, a laser light source 10, a light modulating element 20, a cross dichroic prism 30, and a projection lens 40.

The laser light source 10 emits laser light. A plurality of laser light sources 10 are provided. Specifically, three laser light sources 10 are provided. A first laser light source 10R of the three laser light sources 10 emits red light. The red light has a wavelength of greater than or equal to 620 nm and less than or equal to 750 nm. A second laser light source 10G of the three laser light sources 10 emits green light. The green light has a wavelength of greater than or equal to 495 nm and less than or equal to 570 nm. A third laser light source 10B of the three laser light sources 10 emits blue light. The blue light has a wavelength of greater than or equal to 400 nm and less than or equal to 480 nm.

The light modulating element 20 modulates light emitted from the laser light source 10 in accordance with image information. The light modulating element 20 is, for example, a transmissive type liquid crystal light valve that transmits light emitted from the laser light source 10. The projector 1000 is a liquid crystal display (LCD) projector.

A plurality of light modulating elements 20 are provided. Specifically, three light modulating elements 20 are provided. A first light modulating element 20R of the three light modulating elements 20 modulates light emitted from the first laser light source 10R. A second light modulating element 20G of the three light modulating elements 20 modulates light emitted from the second laser light source 10G. A third light modulating element 20B of the three light modulating elements 20 modulates light emitted from the third laser light source 10B.

In the illustrated example, the projector 1000 includes a compensating plate 50 and a polarizing plate 52. The compensating plate 50 is provided in an optical path between the laser light source 10 and the light modulating element 20. The compensating plate 50 can compensate for the amount that polarization of the light emitted from the laser light source 10 is disturbed in a liquid crystal layer of the light modulating element 20. The polarizing plate 52 is provided in an optical path between the light modulating element 20 and the cross dichroic prism 30. The polarizing plate 52 can adjust polarization of light transmitted through the light modulating element 20.

The cross dichroic prism 30 is formed by bonding four rectangular prisms together, and a dielectric multilayer film that reflects red light and a dielectric multilayer film that reflects blue light are arranged in a criss-cross manner in the rectangular prism. Three color lights are synthesized by these dielectric multilayer films, and light representing a color image is formed.

The projection lens 40 projects the light synthesized by the cross dichroic prism 30 onto a screen (not illustrated). An enlarged image is displayed on the screen.

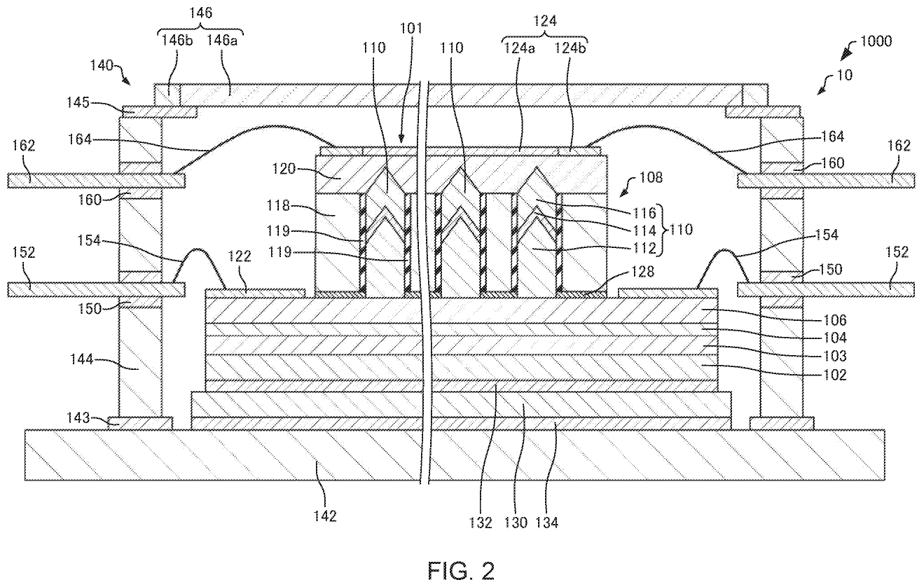

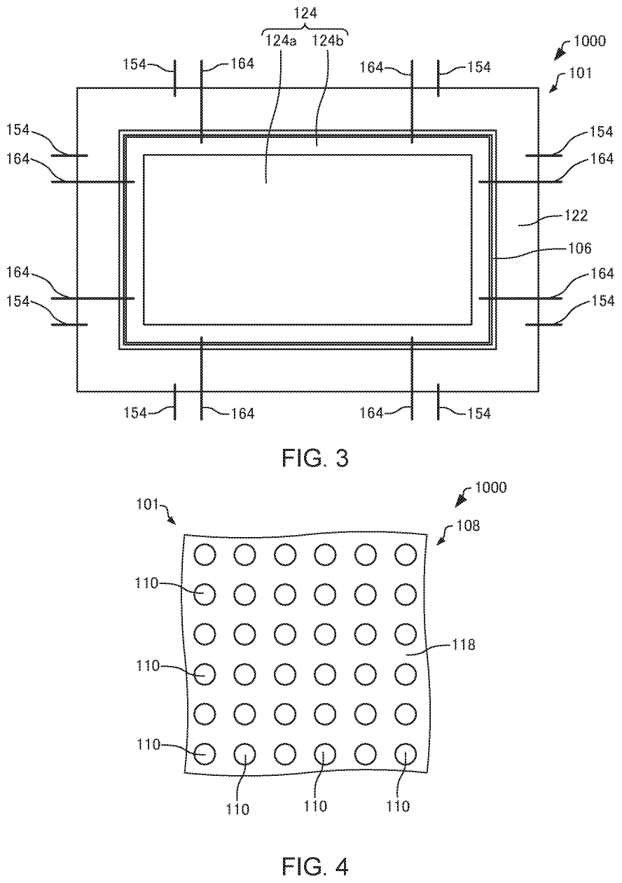

Next, a configuration of the laser light source 10 will be described. FIG. 2 is a cross-sectional view schematically illustrating the laser light source 10. FIG. 3 is a plan view schematically illustrating a light emitting element 101 of the laser light source 10. As illustrated in FIG. 2, the laser light source 10 includes, for example, the light emitting element 101, a submount 130, and a package 140.

The light emitting element 101 is housed in the package 140. As illustrated in FIGS. 2 and 3, the light emitting element 101 includes, for example, a substrate 102, a buffer layer 103, a reflective layer 104, a buffer layer 106, a photonic crystal structure 108, a semiconductor layer 120, a first electrode 122, and a second electrode 124.

The substrate 102 is, for example, a sapphire substrate, a SiC substrate, a Si substrate, a GaAs substrate, a GaN substrate, and the like. Note that, considering the cooling efficiency, the substrate 102 may be an Si substrate having high thermal conductivity. As illustrated in FIG. 2, the light emitting element 101 is mounted on the submount 130 with the substrate 102 side facing the submount 130 side. In other words, the light emitting element 101 is mounted in a junction up state.

The buffer layer 103 is provided on the substrate 102, and the buffer layer 103 is located on the upper side of the substrate 102. The buffer layer 103 may relieve stress based on a difference in lattice constants between the substrate 102 and the reflective layer 104.

Note that “upper” refers to a direction away from the substrate 102 when seen from a light emitting layer 114 in a lamination direction of a semiconductor layer 112 and the light emitting layer 114 of the photonic crystal structure 108 (hereinafter, also simply referred to as a “lamination direction”), and “lower” refers to a direction approaching the substrate 102 when seen from the light emitting layer 114 in the lamination direction.

The reflective layer 104 is provided on the buffer layer 103. The reflective layer 104 is, for example, a distribution Bragg reflector (DBR) layer. The reflective layer 104 reflects light generated in the light emitting layer 114 toward the second electrode 124 side.

The buffer layer 106 is provided on the reflective layer 104. The buffer layer 106 is, for example, a Si doped n-type GaN layer. In the illustrated example, a mask layer 128 for selectively growing a columnar portion 110 is provided on the buffer layer 106. The mask layer 128 is a nonpolar layer, for example a silicon oxide layer such as an αSiO₂ layer, a silicon nitride layer, and the like.

The photonic crystal structure 108 is provided on the substrate 102. In the illustrated example, the photonic crystal structure 108 is provided on the substrate 102 being intervened by the buffer layers 103 and 106 and the reflective layer 104. The photonic crystal structure 108 includes the columnar portion 110, a light propagation layer 118, and a passivation layer 119. The photonic crystal structure 108 may exhibit the effect of the photonic crystal, causing light emitted by the light emitting layer 114 of the photonic crystal structure 108 to be confined in an in-plane direction of the substrate 102 and be emitted in a normal direction of the substrate 102. Here, the “in-plane direction of the substrate 102” refers to a direction orthogonal to the lamination direction. The “normal direction of the substrate 102” refers to the lamination direction. The laser light source 10 is a photonic crystal laser having the photonic crystal structure 108.

The columnar portion 110 is provided on the buffer layer 106. Here, FIG. 4 is a plan view schematically illustrating the photonic crystal structure 108. Note that, for convenience, the passivation layer 119 is omitted from FIG. 4.

As illustrated in FIG. 4, a planar shape of the columnar portion 110 is, for example, a circle. Although not illustrated, the planar shape of the columnar portion 110 may be a polygon such as a regular hexagon. A diameter of the columnar portion 110 is, for example, on the order of nm, and specifically, is greater than or equal to 10 nm and less than or equal to 500 nm. The columnar portion 110 is also referred to as a nanocolumn, a nanowire, a nanorod, and a nanopillar, for example. The columnar portion 110 has a size in the lamination direction of, for example, greater than or equal to 0.1 μm and less than or equal to 5 μm.

Note that a “diameter” is a diameter when a planar shape of the columnar portion 110 is a circle, and is a diameter of the smallest circle including a polygon therein, namely, the smallest inclusion circle when a planar shape of the columnar portion 110 is polygonal. Further, the “planar shape” refers to a shape when seen from the lamination direction.

A plurality of columnar portions 110 are provided. The columnar portions 110 are arranged periodically at a predetermined pitch in a predetermined direction. In the example illustrated in FIG. 4, the plurality of columnar portions 110 are arranged in a square lattice shape, for example, when seen from the lamination direction.

As illustrated in FIG. 2, the columnar portion 110 includes the semiconductor layer 112, the light emitting layer 114, and a semiconductor layer 116.

The semiconductor layer 112 is provided on the buffer layer 106. The semiconductor layer 112 is, for example, an Si doped n-type GaN layer.

The light emitting layer 114 is provided on the semiconductor layer 112. The light emitting layer 114 is provided between the semiconductor layer 112 and the semiconductor layer 116. The light emitting layer 114 has a quantum well structure constituted by a GaN layer and an InGaN layer, for example. The light emitting layer 114 is a layer capable of emitting light by being injected a current.

The semiconductor layer 116 is provided on the light emitting layer 114. The semiconductor layer 116 is a layer of a conductive type different from the conductive type of the semiconductor layer 112. The semiconductor layer 116 is, for example, an Mg doped p-type GaN layer. The semiconductor layers 112 and 116 are a cladding layer having a function of confining light in the light emitting layer 114. In the illustrated example, upper surfaces of the semiconductor layers 112 and 116 and the light emitting layer 114 are facet surfaces.

The light propagation layer 118 is provided between adjacent columnar portions 110. In the illustrated example, the light propagation layer 118 is provided on the mask layer 128. The light propagation layer 118 is, for example, a GaN layer and the like. Light generated in the light emitting layer 114 can propagate through the light propagation layer 118.

The passivation layer 119 is provided on a side surface of the light emitting layer 114. The passivation layer 119 can suppress non-emission recombination at the side surface of the light emitting layer 114. The passivation layer 119 is, for example, a silicon oxide layer, a silicon nitride layer, and the like.

In the laser light source 10, the p-type semiconductor layer 116, the impurity-undoped light emitting layer 114, and the n-type semiconductor layer 112 constitute a pin diode. The semiconductor layers 112 and 116 are a layer having a larger band gap than the band gap of the light emitting layer 114. In the laser light source 10, when a forward bias voltage of the pin diode is applied and a current is injected between the first electrode 122 and the second electrode 124, recombination of electrons and holes occurs in the light emitting layer 114. This recombination creates light emission. Light generated in the light emitting layer 114 propagates through the light propagation layer 118 in the direction orthogonal to the lamination direction by the semiconductor layers 112 and 116, forms a standing wave due to the effect of the photonic crystal by the photonic crystal structure 108, and is confined in the direction orthogonal to the lamination direction (the in-plane direction of the substrate 102). The confined light receives a gain in the light emitting layer 114 and laser-oscillates. In other words, the light generated in the light emitting layer 114 resonates in the in-plane direction of the substrate 102 by the photonic crystal structure 108 and laser-oscillates. Then, +1-order diffraction light and −1-order diffraction light travel in the lamination direction as laser light.

The laser light directed toward the reflective layer 104 side of the laser light traveling in the lamination direction is reflected by the reflective layer 104 and directed toward the second electrode 124 side. In this way, the laser light source 10 can emit light from the second electrode 124 side.

A radiation angle of the light emitted from the laser light source 10 is less than 1°, and is smaller than the radiation angle of an end face type semiconductor laser or a Vertical Cavity Surface Emitting Laser (VCSEL), for example. The laser light source 10 can have a small etendue.

The semiconductor layer 120 is provided on the photonic crystal structure 108. The semiconductor layer 120 is, for example, an Mg doped p-type GaN layer.

The first electrode 122 is provided on the buffer layer 106. The buffer layer 106 may be in ohmic contact with the first electrode 122. In the illustrated example, the first electrode 122 is electrically coupled to the semiconductor layer 112 via the buffer layer 106. The first electrode 122 is one electrode configured to inject a current into the light emitting layer 114. As the first electrode 122, for example, a Ti layer, an Al layer, and an Au layer laminated in this order from the buffer layer 106 side is used.

The second electrode 124 is provided on the semiconductor layer 120. The semiconductor layer 120 may be in ohmic contact with the second electrode 124. The second electrode 124 is electrically coupled to the semiconductor layer 116. In the illustrated example, the second electrode 124 is electrically coupled to the semiconductor layer 116 via the semiconductor layer 120. The second electrode 124 is the other electrode configured to inject a current into the light emitting layer 114.

The second electrode 124 includes, for example, a transparent portion 124a that is transparent to light created by the light emitting layer 114, and a non-transparent portion 124b that is not transparent to the light created by the light emitting layer 114. A material for the transparent portion 124a is indium tin oxide (ITO) and indium zinc oxide (IZO), for example. A material for the non-transparent portion 124b is the same as the material for the first electrode 122, for example. In the example illustrated in FIG. 3, the non-transparent portion 124b surrounds the transparent portion 124a when seen from the lamination direction.

As illustrated in FIG. 2, the submount 130 is provided between the substrate 102 and a base 142 of the package 140. A material for the submount 130 is, for example, copper, aluminum, or the like. The submount 130 and the substrate 102 are bonded together by a bonding layer 132. The submount 130 and the base 142 are bonded together by a bonding layer 134. For example, solder or silver paste is used as the bonding layers 132 and 134.

The package 140 includes the base 142, a wall portion 144, and a lid portion 146. A material for the base 142 is, for example, copper. The wall portion 144 is provided on the base 142 being intervened by a bonding layer 143. A material for the wall portion 144 is metal. For example, silver solder is used as the bonding layer 143.

The wall portion 144 is provided with a first support portion 150 and a first coupling terminal 152 supported by the first support portion 150. A plurality of first support portions 150 and first coupling terminals 152 are provided. The first coupling terminal 152 is electrically coupled to the first electrode 122 via a first wire 154.

The wall portion 144 is provided with a second support portion 160 and a second coupling terminal 162 supported by the second support portion 160. A plurality of second support portions 160 and second coupling terminals 162 are provided. The second coupling terminal 162 is electrically coupled to the second electrode 124 via a second wire 164. A material for the support portions 150 and 160 is, for example, low melting glass. A material for the coupling terminals 152 and 162 and the wires 154 and 164 is, for example, metal.

The lid portion 146 is bonded to the wall portion 144 being intervened by a metal frame 145. A material for the metal frame 145 is, for example, Kovar. The lid portion 146 is seam welded to the wall portion 144 being intervened by the metal frame 145, for example. The lid portion 146 transmits light emitted from the light emitting element 101. The lid portion 146 includes, for example, a first portion 146a made of glass and a second portion 146b that surrounds the first portion 146a and is made of low melting glass.

Note that the light emitting layer 114 of the InGaN system is described above, but any material system capable of emitting light by being injected a current can be used as the light emitting layer 114 in accordance with a wavelength of the emitted light. For example, semiconductor materials such as an AlGaN system, an AlGaAs system, an InGaAs system, an InGaAsP system, an InP system, a GaP system, and an AlGaP system may be used.

In the projector 1000 described above, a first diameter of the columnar portion 110 in the first laser light source 10R, a second diameter of the columnar portion 110 in the second laser light source 10G, and a third diameter of the columnar portion 110 in the third laser light source 10B may be different. In other words, the first diameter may be greater than the second diameter, and the second diameter may be greater than the third diameter. The first diameter is, for example, greater than or equal to 50 nm and less than or equal to 400 nm. The second diameter is, for example, greater than or equal to 50 nm and less than or equal to 300 nm. The third diameter is, for example, greater than or equal to 50 nm and less than or equal to 200 nm.

Further, a first pitch of the columnar portions 110 in the first laser light source 10R, a second pitch of the columnar portions 110 in the second laser light source 10G, and a third pitch of the columnar portions 110 in the third laser light source 10B may be different. In other words, the first pitch may be greater than the second pitch, and the second pitch may be greater than the third pitch. The first pitch is, for example, greater than or equal to 100 nm and less than or equal to 450 nm. The second pitch is, for example, greater than or equal to 100 nm and less than or equal to 350 nm. The third pitch is, for example, greater than or equal to 100 nm and less than or equal to 250 nm.

Further, a first size in the lamination direction of the columnar portion 110 of the first laser light source 10R, a second size in the lamination direction of the columnar portion 110 in the second laser light source 10G, and a third size in the lamination direction of the columnar portion 110 of the third laser light source 10B may be different. In other words, the first size may be smaller than the second size, and the second size may be smaller than the third size.

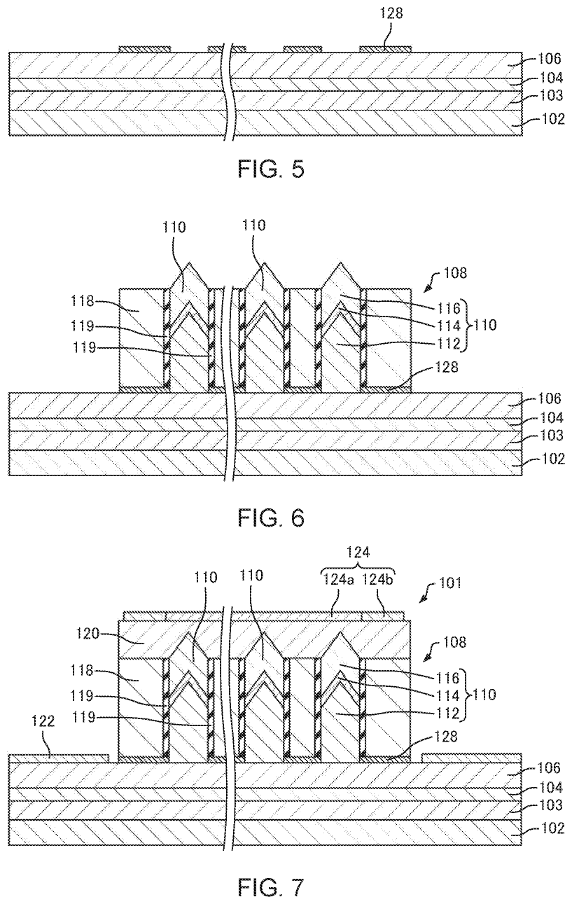

Next, a method for manufacturing the laser light source 10 will be described with reference to the drawings. FIGS. 5 to 7 are cross-sectional views schematically illustrating manufacturing steps of the laser light source 10.

As illustrated in FIG. 5, the buffer layer 103, the reflective layer 104, and the buffer layer 106 are epitaxially grown in this order on the substrate 102. Examples of the method of epitaxial growth include a Metal Organic Chemical Vapor Deposition (MOCVD) method, a Molecular Beam Epitaxy (MBE) method, and the like.

Next, the mask layer 128 is formed on the buffer layer 106 using, for example, the MOCVD method, the MBE method, or the like, and patterned into a predetermined shape by photolithography and etching.

As illustrated in FIG. 6, the semiconductor layer 112, the light emitting layer 114, and the semiconductor layer 116 are epitaxially grown in this order on the buffer layer 106 with the mask layer 128 as a mask. Examples of the method of epitaxial growth include the MOCVD method, the MBE method, and the like. The columnar portion 110 can be formed by this step.

Next, the passivation layer 119 is formed on the side surface and the upper surface of the columnar portion 110. The passivation layer 119 is formed by, for example, a Chemical Vapor Deposition (CVD) method, a sputtering method, or the like.

Next, the light propagation layer 118 is formed between adjacent columnar portions 110 by a spin coating method or the like.

Next, the passivation layer 119 provided on the upper surface of the columnar portion 110 is removed by etching or the like. The photonic crystal structure 108 can be formed by this step.

As illustrated in FIG. 7, the semiconductor layer 120 is formed on the photonic crystal structure 108 by the MOCVD method, the MBE method, or the like, for example.

Next, the first electrode 122 and the second electrode 124 are formed by, for example, a vacuum deposition method. The light emitting element 101 can be formed by this step.

As illustrated in FIG. 2, after the submount 130 is bonded to the base 142 of the package 140, the light emitting element 101 is mounted on the submount 130. Next, the first electrode 122 and the first coupling terminal 152 are electrically coupled by the first wire 154, and the second electrode 124 and the second coupling terminal 162 are electrically coupled by the second wire 164. Next, the lid portion 146 of the package 140 is bonded to the wall portion 144.

The laser light source 10 can be formed by the steps described above.

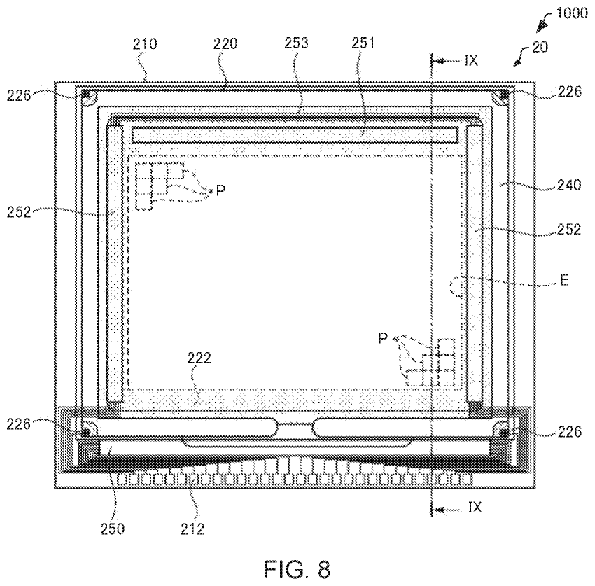

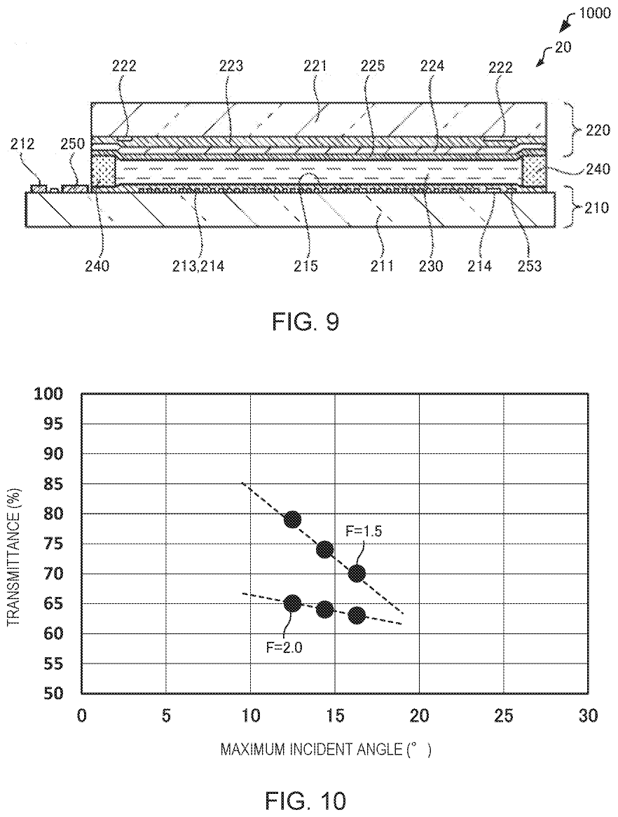

Next, a configuration of the light modulating element 20 will be described. FIG. 8 is a plan view schematically illustrating the light modulating element 20. FIG. 9 is a cross-sectional view taken along an IX-IX line of FIG. 8 schematically illustrating the light modulating element 20.

As illustrated in FIGS. 8 and 9, the light modulating element 20 includes an element substrate 210 and a counter substrate 220 that are disposed facing each other, and a liquid crystal layer 230 sandwiched by the pair of the substrates. A base material 211 of the element substrate 210 and a base material 221 of the counter substrate 220 are a quartz substrate, a glass substrate, or the like that transmits light emitted from the laser light source 10.

The element substrate 210 is substantially larger than the counter substrate 220. The element substrate 210 and the counter substrate 220 are bonded together being intervened by a sealing material 240 arranged in a frame shape along an outer edge portion of the counter substrate 220. A liquid crystal having positive or negative dielectric anisotropy is encapsulated in a gap between the element substrate 210 and the counter substrate 220, and the liquid crystal layer 230 is formed. The sealing material 240 is, for example, an adhesive such as thermosetting or ultraviolet-curable epoxy resin. A spacer (not illustrated) for holding a gap between the pair of the substrates constant is mixed into the sealing material 240.

A display region E in which a plurality of pixels P are arranged in a matrix is provided on an inner side of the sealing material 240. The counter substrate 220 is provided with a partition portion 222 that surrounds the display region E between the sealing material 240 and the display region E. A material for the partition portion 222 is, for example, a light blocking metal, an alloy or an oxide of the metal, or the like. Note that the display region E may include, in addition to the plurality of pixels P contributing to display, dummy pixels arranged to surround the plurality of pixels P.

The element substrate 210 is provided with a terminal portion in which a plurality of external coupling terminals 212 are arranged. A data line drive circuit 250 is provided between a first side portion of the element substrate 210 along the terminal portion and the sealing material 240. Further, an inspection circuit 251 is provided between the sealing material 240 along a second side portion facing to the first side portion and the display region E. Furthermore, a scanning line drive circuit 252 is provided between the sealing material 240 along a third side portion and a fourth side portion that are orthogonal to the first side portion and face each other, and the display region E. A plurality of wiring lines 253 that couple the two scanning line drive circuits 252 are provided between the sealing material 240 on the second side portion and the inspection circuit 251.

The wiring lines coupled to the data line drive circuit 250 and the scanning line drive circuits 252 are coupled to the plurality of external coupling terminals 212 arranged along the first side portion.

As illustrated in FIG. 9, the element substrate 210 includes, for example, the base material 211, a Thin Film Transistor (TFT) 213 and a pixel electrode 214 that are formed on a surface of the base material 211 on the liquid crystal layer 230 side, and an alignment layer 215 covering the pixel electrode 214. The TFT 213 and the pixel electrode 214 are components of the pixel P.

The TFT 213 changes a voltage between the pixel electrode 214 and a counter electrode 224 in accordance with input image information, and modulates light passing through the liquid crystal layer 230. In this way, the brightness can be changed for each pixel P, and an image can be formed. The TFT 213 is a thin film transistor.

The counter substrate 220 includes, for example, the base material 221, and the partition portion 222, a planarization layer 223, the counter electrode 224, and the alignment layer 225 that are laminated in order on a surface of the base material 221 on the liquid crystal layer 230 side.

As illustrated in FIG. 8, the partition portion 222 is provided in a position that surrounds the display region E and also overlaps the scanning line drive circuits 252 and the inspection circuit 251 in a plan view. In this way, the partition portion 222 has functions of blocking light incident on the peripheral circuit including these drive circuits from the counter substrate 220 side, and preventing the peripheral circuit from malfunctioning due to light. Further, unnecessary stray light is blocked from entering the display region E to ensure high contrast in display of the display region E. A size of the transparent portion 124a of the second electrode 124 illustrated in FIG. 3 is the same as or substantially greater than the display region E. Thus, the light emitted from the laser light source 10 can be uniformly radiated to the display region E without waste.

The planarization layer 223 is formed of an inorganic material such as a silicon oxide, for example, has light-transmissive property, and is provided to cover the partition portion 222. The planarization layer 223 has a film thickness to an extent that can mitigate surface irregularities of the counter electrode 224 formed on the planarization layer 223.

The counter electrode 224 is formed of a transparent conductive film such as ITO and IZO, for example. The counter electrode 224 covers the planarization layer 223. As illustrated in FIG. 8, the counter electrode 224 is electrically coupled to wiring on the element substrate 210 side by conducting portions 226 provided at four corners of the counter substrate 220.

A material for the alignment layer 215 covering the pixel electrode 214 and the alignment layer 225 covering the counter electrode 224 is, for example, an inorganic material such as a silicon oxide. The alignment layers 215 and 225 may be an organic alignment layer, such as polyimide, in addition to the inorganic alignment layer.

The projector 1000 has the following characteristics, for example.

In the projector 1000, the laser light source 10 includes the substrate 102 and the photonic crystal structure 108 that includes the light emitting layer 114 that emits light, and causes the light emitted by the light emitting layer 114 to be confined in the in-plane direction of the substrate 102 and be emitted in the normal direction of the substrate 102. Thus, in the projector 1000, a radiation angle of the light emitted from the laser light source 10 can be reduced as compared to a case where, for example, an LED or a semiconductor laser of an end face emission type is used as a light source, and the light modulating element 20 can irradiate light without using a condensing lens, a rod integrator, and the like. Therefore, the size of the projector 1000 can be reduced.

Furthermore, since a condensing lens, a rod integrator, and the like are not used, a loss in the amount of light in the condensing lens and the like can be reduced, and the brightness can be increased. As a result, the efficient projector 1000 can be achieved. Furthermore, a radiation angle of the light emitted from the laser light source 10 can be reduced, and thus the light incident on the TFT 213 and the wiring of the light modulating element 20 can be reduced. Thus, a transmittance of the light modulating element 20 can be increased, and the bright projector 1000 can be achieved. Furthermore, a phenomenon in which image quality becomes deteriorated, such as pixel unevenness and flicker is generated due to light being incident on the TFT 213, can be suppressed. Furthermore, the projection lens 40 having a small aperture with a great F value (F-number) can be used.

Here, FIG. 10 is a graph illustrating a relationship between a maximum incident angle of light incident on a transmissive type liquid crystal light valve and a transmittance of light in a projection lens. As the transmittance of light in the projection lens is higher, the brighter projector can be achieved. A lens was arranged between a light source and the liquid crystal light valve, and an incident angle of light on the liquid crystal light valve was changed by changing an F value of the lens. Further, projection lenses having an F value of 1.5 and 2.0 were prepared.

As illustrated in FIG. 10, it is clear that a smaller incident angle of light on the liquid crystal light valve increases a transmittance of light in the projection lens, and thus the brighter projector can be achieved.

Furthermore, although not illustrated, when the light modulating element 20 includes a microlens array for condensing light into the pixel electrode 214, a radiation angle of the light emitted from the laser light source 10 is small, and thus lens power of the microlens array can be reduced. Thus, depolarization in the microlens array is small, and the contrast of the projector 1000 can be improved. Furthermore, condensation of light can be suppressed, and thus the life of the light modulating element 20 can be improved.

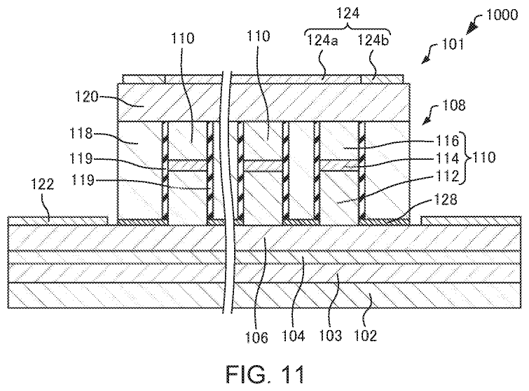

Note that, as illustrated in FIG. 2, the upper surfaces of the semiconductor layers 112 and 116 and the light emitting layer 114 of the light emitting element 101 are facet surfaces in the description above, but as illustrated in FIG. 11, the upper surfaces of the semiconductor layers 112 and 116 and the light emitting layer 114 of the light emitting element 101 may be c-surfaces. For example, the upper surfaces of the semiconductor layers 112 and 116 and the light emitting layer 114 can be set as c-surfaces by changing a growth condition and a material for the columnar portion 110.

### 1.2. Modified Example

### 1.2.1. First Modified Example

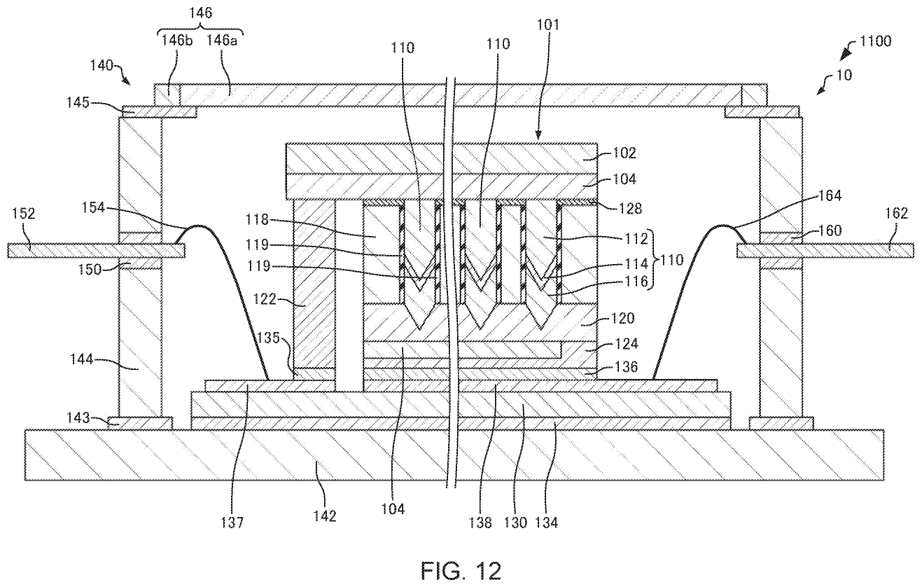

Next, a projector 1100 according to a first modified example of the first embodiment will be described with reference to the drawing. FIG. 12 is a cross-sectional view schematically illustrating a laser light source 10 of the projector 1100 according to the first modified example of the first embodiment.

Hereinafter, differences between the projector 1100 according to the first modified example of the first embodiment and the example of the projector 1000 according to the first embodiment described above will be described, and descriptions of the same points will be omitted. This is the same for a projector according to a second modified example of the first embodiment described later.

In the projector 1000 described above, as illustrated in FIG. 2, the light emitting element 101 is mounted on the submount 130 with the substrate 102 side facing the submount 130 side. In contrast, in the projector 1100, as illustrated in FIG. 12, the light emitting element 101 is mounted on the submount 130 with the second electrode 124 side facing the submount 130 side. In other words, the light emitting element 101 is mounted in a junction down state.

In the projector 1100, the first electrode 122 is a bump. The first electrode 122 is electrically coupled to the first coupling terminal 152 via a bonding layer 135, wiring 137, and the first wire 154. The second electrode 124 is electrically coupled to the second coupling terminal 162 via a bonding layer 136, wiring 138, and the second wire 164. A material for the second electrode 124 is, for example, a metal that is not transparent to light created by the light emitting layer 114. For example, solder is used as the bonding layers 135 and 136. A material for the wiring 137 and 138 is, for example, copper or aluminum.

The reflective layer 104 is provided between the semiconductor layer 120 and the second electrode 124. The reflective layer 104 reflects light, which is traveling toward the second electrode 124 side, to the substrate 102 side. In this way, the light emitting element 101 emits light from the substrate 102 side. The reflective layer 104 is, for example, a DBR layer and a metal layer. The substrate 102 is, for example, a sapphire substrate.

### 1.2.2. Second Modified Example

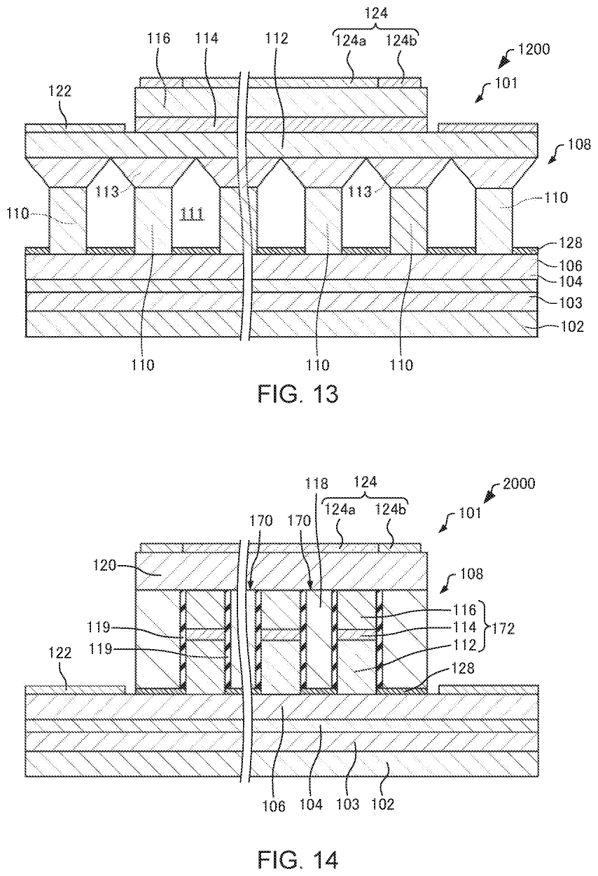

Next, a projector 1200 according to the second modified example of the first embodiment will be described with reference to the drawing. FIG. 13 is a cross-sectional view schematically illustrating a light emitting element 101 of the projector 1200 according to the second modified example of the first embodiment.

In the light emitting element 101 of the projector 1000 described above, as illustrated in FIG. 2, the columnar portion 110 of the photonic crystal structure 108 includes the light emitting layer 114. In contrast, in the light emitting element 101 of the projector 1200, as illustrated in FIG. 13, the columnar portion 110 does not include the light emitting layer 114.

In the projector 2000, a material for the columnar portion 110 is, for example, Si doped n-type GaN. The photonic crystal structure 108 is constituted by the columnar portion 110 and a gap 111 between adjacent columnar portions 110. In the illustrated example, the photonic crystal structure 108 includes a tapered portion 113, on the columnar portion 110, which gradually increases in diameter toward the upper side. A material for the tapered portion 113 is the same as that for the columnar portion 110. Note that the tapered portion 113 may not be provided.

The semiconductor layer 112 is provided on the tapered portion 113. The light emitting layer 114 is provided on the semiconductor layer 112. The semiconductor layer 116 is provided on the light emitting layer 114. The first electrode 122 is provided on the semiconductor layer 112. The second electrode 124 is provided on the semiconductor layer 116. Note that, although not illustrated, the semiconductor layers 112 and 116 and the light emitting layer 114 may be provided between the substrate 102 and the photonic crystal structure 108.

When the photonic crystal structure 108 does not include the light emitting layer 114 as in the projector 2000, light leaked from the light emitting layer 114 toward the photonic crystal structure 108 side is confined in the direction orthogonal to the lamination direction and emitted in the lamination direction.

### 2. Second Embodiment

### 2.1. Projector

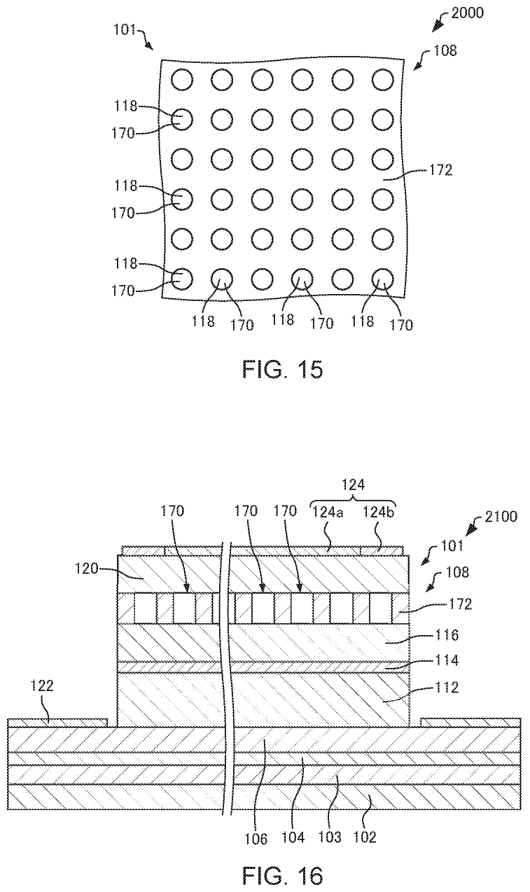

Next, a projector 2000 according to a second embodiment will be described with reference to the drawings. FIG. 14 is a cross-sectional view schematically illustrating a light emitting element 101 of the projector 2000 according to the second embodiment. FIG. 15 is a plan view schematically illustrating a photonic crystal structure 108 of the projector 2000 according to the second embodiment. Note that, for convenience, a passivation layer 119 is omitted from FIG. 15.

Hereinafter, differences between the projector 2000 according to the second embodiment and the example of the projector 1000 according to the first embodiment described above will be described, and descriptions of the same points will be omitted.

As illustrated in FIGS. 2 and 4, in the projector 1000 described above, the photonic crystal structure 108 includes the columnar portions 110 arranged periodically. In contrast, as illustrated in FIGS. 14 and 15, in the projector 2000, the photonic crystal structure 108 includes a photonic crystal layer 172 provided with pores 170 periodically. In this way, the light emitting element 101 can exhibit the photonic crystal effect. The plurality of pores 170 are provided. In the illustrated example, the photonic crystal structure 108 is formed of the photonic crystal layer 172 provided with the pores 170 periodically.

The photonic crystal layer 172 includes a semiconductor layer 112, a light emitting layer 114 provided on the semiconductor layer 112, and a semiconductor layer 116 provided on the light emitting layer 114. The photonic crystal layer 172 is formed by forming the semiconductor layer 112, the light emitting layer 114, and the semiconductor layer 116, and then forming the pores 170 by patterning with using photolithography and etching, for example.

The passivation layer 119 is provided on an interior surface of the pore 170. A light propagation layer 118 is provided in the pore 170. In the illustrated example, the pore 170 is filled with the light propagation layer 118 and the passivation layer 119.

In the projector 2000, the photonic crystal structure 108 can be easily formed by simply forming the pore 170 in the photonic crystal layer 172.

### 2.2. Modified Example

Next, a projector 2100 according to a modified example of the second embodiment will be described with reference to the drawing. FIG. 16 is a cross-sectional view schematically illustrating a light emitting element 101 of the projector 2100 according to the modified example of the second embodiment.

Hereinafter, differences between the projector 2100 according to the modified example of the second embodiment and the example of the projector 2000 according to the second embodiment described above will be described, and descriptions of the same points will be omitted.

In the light emitting element 101 of the projector 2000 described above, as illustrated in FIG. 14, the photonic crystal layer 172 includes the light emitting layer 114. In contrast, in the light emitting element 101 of the projector 2100, as illustrated in FIG. 16, the photonic crystal layer 172 does not include the light emitting layer 114.

In the projector 2100, a material for the photonic crystal layer 172 is, for example, Mg doped p-type GaN. The photonic crystal layer 172 is provided on the semiconductor layer 116. The semiconductor layer 120 is provided on the photonic crystal layer 172.

As long as the features and effects described herein are provided, a part of the configuration of the present disclosure may be omitted, and the various embodiments and modified examples may be combined.

The present disclosure is not limited to the embodiments described above, and various modifications are further possible. For example, the present disclosure includes configurations that are substantially the same (for example, in function, method, and results, or in objective and effects) as the configurations described in the embodiments. The present disclosure also includes configurations in which non-essential elements described in the embodiments are replaced by other elements. The present disclosure also includes configurations having the same effects as those of the configurations described in the embodiments, or configurations capable of achieving the same objectives as those of the configurations described in the embodiments. The present disclosure further includes configurations obtained by adding known art to the configurations described in the embodiments.

Some embodiments of the present disclosure have been described in detail above, but a person skilled in the art will readily appreciate that various modifications can be made from the embodiments without materially departing from the novel teachings and effects of the present disclosure. Accordingly, all such modifications are assumed to be included in the scope of the present disclosure.

What is claimed is:

1. A projector comprising:
a laser light source; and
a light modulating element that modulates light emitted from the laser light source in accordance with image information,
the laser light source including:
a substrate; and
a photonic crystal structure that includes a light emitting layer that emits light, and causes the light emitted by the light emitting layer to be confined in an in-plane direction of the substrate and be emitted in a normal direction of the substrate.

2. The projector according to claim 1, wherein
the photonic crystal structure includes columnar portions arranged periodically.

3. The projector according to claim 2, wherein
each of the columnar portions includes the light emitting layer.

4. The projector according to claim 1, wherein
the photonic crystal structure includes a layer provided with pores periodically.

5. The projector according to claim 4, wherein
the layer includes the light emitting layer.

6. A projector comprising:
a laser light source; and
a light modulating element that modulates light emitted from the laser light source in accordance with image information,
the laser light source including:
a substrate;
a light emitting layer that emits light; and
a photonic crystal structure that causes the light emitted by the light emitting layer to be confined in an in-plane direction of the substrate and be emitted in a normal direction of the substrate.

7. The projector according to claim 6, wherein
the photonic crystal structure includes columnar portions arranged periodically.

8. The projector according to claim 6, wherein
the photonic crystal structure includes a layer provided with pores periodically.
